(19) United States
(12) Patent Application Publication
(10) Pub. No.: US 2024/0165825 A1
(43) Pub. Date: May 23, 2024

(54) Elastic Clip Installation System

(71) Applicants: TE Connectivity Solutions GmbH, Schaffhausen (CH); Tyco Electronics (Shanghai) Co., Ltd., Shanghai (CN); Kunshan League Automechanism Co., Ltd, Kunshan City (CN)

(72) Inventors: Rong Zhang, Shanghai (CN); Dandan (Emily) Zhang, Shanghai (CN); Roberto Francisco-Yi Lu, Bellevue, WA (US); Lei (Alex) Zhou, Shanghai (CN); Zongjie (Jason) Tao, Shanghai (CN); Xianghao (Jorge) Bao, Shanghai (CN); Yong Wang, Kunshan City (CN); Haidong Wu, Kunshan City (CN)

(73) Assignees: TE Connectivity Solutions GmbH, Schaffhausen (CH); Tyco Electronics (Shanghai) Co., Ltd., Shanghai (CN); Kunshan League Automechanism Co., Ltd, Kunshan City (CN)

(21) Appl. No.: 18/515,595

(22) Filed: Nov. 21, 2023

(30) Foreign Application Priority Data
Nov. 22, 2022 (CN) 202211464998.1

(51) Int. Cl. B25J 15/00; B25J 19/06

(52) U.S. Cl. CPC B25J 15/0019; B25J 19/06

(57) ABSTRACT

An elastic clip installation system includes a loading tray on which an elastic clip to be installed is loaded and a pickup device picking up the elastic clip from the loading tray. The pickup device includes a pair of clamping claws and a holding claw. The clamping claws grip the elastic clip from a left side and a right side of the elastic clip. The holding claw holds the elastic clip at a predetermined position on the loading tray to prevent movement of the elastic clip when the elastic clip is gripped by the clamping claws.

### CROSS-REFERENCE TO RELATED APPLICATION

This application claims the benefit of the filing date under 35 U.S.C. § 119(a)-(d) of Chinese Patent Application No. 202211464998.1, filed on Nov. 22, 2022.

### FIELD OF THE INVENTION

The present invention relates to an installation system, in particular to an installation system for installing an elastic cplip onto a shielding shell of a connector.

### BACKGROUND

It is sometimes necessary to install a heat sink on a shielding shell of a connector to prevent the temperature of the connector from being too high. In the prior art, an elastic clip installed onto the shielding shell is usually used to fix the heat sink onto the shielding shell. However, in the prior art, there is no installation device that can automatically install the elastic clip, requiring manual installation of the elastic clip, which reduces the installation efficiency of the elastic clip.

### SUMMARY

An elastic clip installation system includes a loading tray on which an elastic clip to be installed is loaded and a pickup device picking up the elastic clip from the loading tray. The pickup device includes a pair of clamping claws and a holding claw. The clamping claws grip the elastic clip from a left side and a right side of the elastic clip. The holding claw holds the elastic clip at a predetermined position on the loading tray to prevent movement of the elastic clip when the elastic clip is gripped by the clamping claws.

### BRIEF DESCRIPTION OF THE DRAWINGS

Features of the present invention will become more apparent by describing in detail exemplary embodiments thereof with reference to the accompanying drawings, in which:

FIG. 1 shows an illustrative perspective view of an elastic clip installation system according to an exemplary embodiment of the present invention;

FIG. 2 shows an illustrative perspective view of an elastic clip according to an exemplary embodiment of the present invention;

FIG. 3 shows an illustrative perspective view of a loading tray according to an exemplary embodiment of the present invention;

FIG. 4 shows an illustrative perspective view of a carrier for loading a pallet according to an exemplary embodiment of the present invention;

FIG. 5 shows an illustrative perspective view of a pickup device according to an exemplary embodiment of the present invention;

FIG. 6 shows a side view of the pickup device according to an exemplary embodiment of the present invention when viewed from the left side;

FIG. 7 shows a cross-sectional side view of a pickup device according to an exemplary embodiment of the present invention; and

FIG. 8 shows a side view of the pickup device according to an exemplary embodiment of the present invention when viewed from the front side.

### DETAILED DESCRIPTION OF EXEMPLARY EMBODIMENTS

Exemplary embodiments of the present disclosure will be described hereinafter in detail with reference to the attached drawings, wherein like reference numerals refer to like elements. The present disclosure may, however, be embodied in many different forms and should not be construed as being limited to the embodiments set forth herein; rather, these embodiments are provided so that the present disclosure will convey the concept of the disclosure to those skilled in the art.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

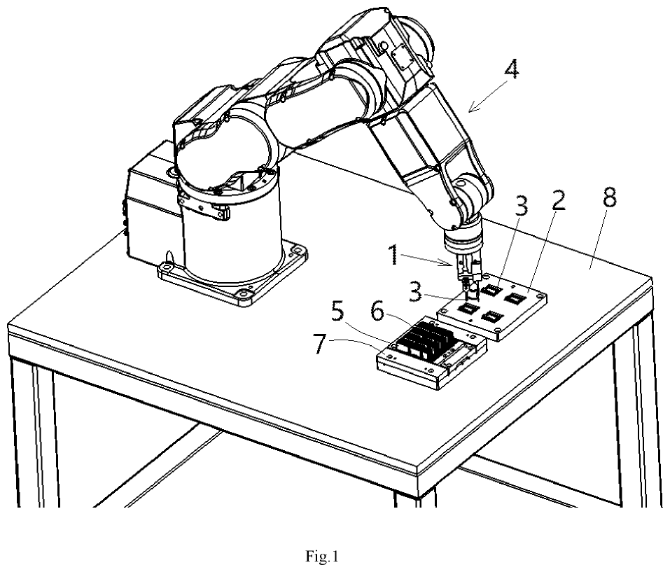

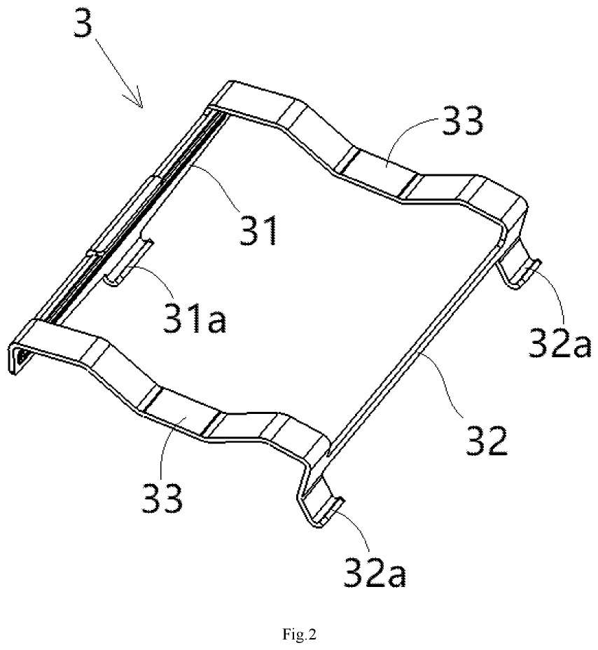

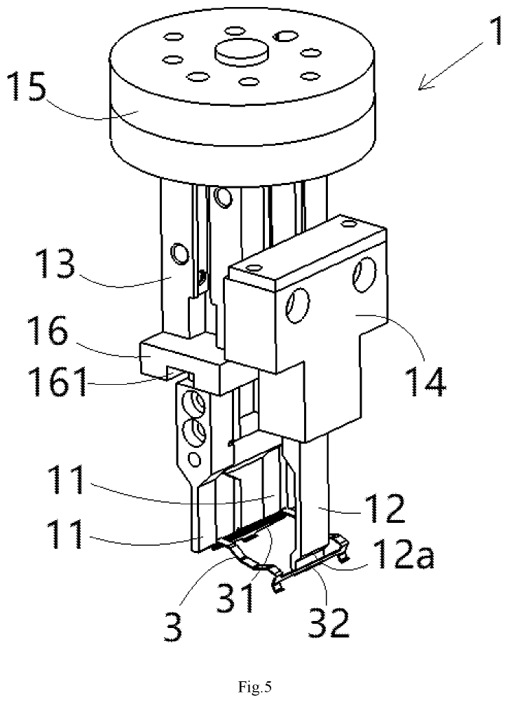

FIG. 1 shows an illustrative perspective view of an elastic clip installation system according to an exemplary embodiment of the present invention. FIG. 2 shows an illustrative perspective view of an elastic clip 3 according to an exemplary embodiment of the present invention. FIG. 5 shows an illustrative perspective view of the pickup device 1 according to an exemplary embodiment of the present invention.

As shown in FIGS. 1-2 and 5, in an exemplary embodiment of the present invention, an elastic clip installation system is disclosed. The elastic clip installation system includes: a pickup device 1 and a loading tray 2. The loading tray 2 is used to load the elastic clip 3 to be installed. The pickup device 1 is used to pick up the clastic clip 3 from the loading tray 2. The pickup device 1 includes a pair of clamping claws 11 and a holding claw 12. The pair of clamping claws 11 are used to grip the elastic clip 3 from the left and right sides. The holding claw 12 is used to hold the elastic clip 3 at a predetermined position on the loading tray 2 to prevent movement of the elastic clip 3 when the elastic clip 3 is gripped by the pair of clamping claws 11.

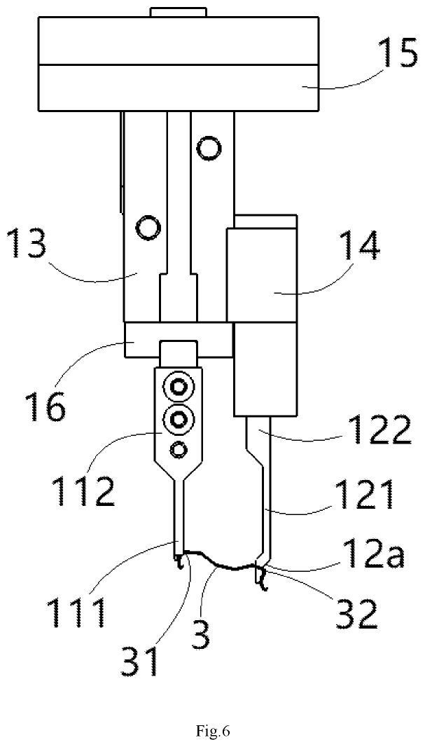

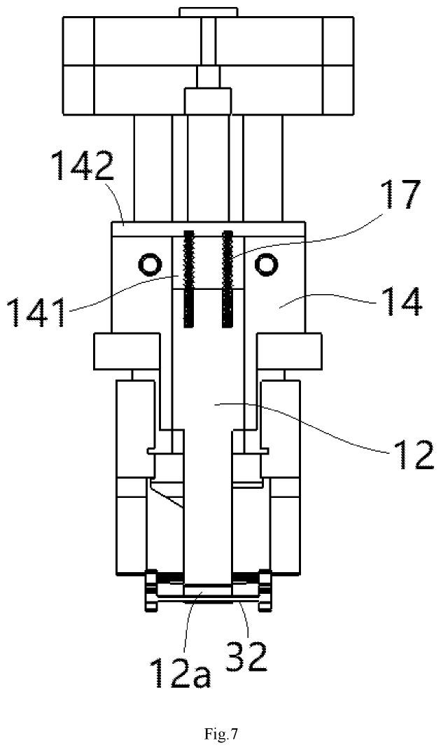

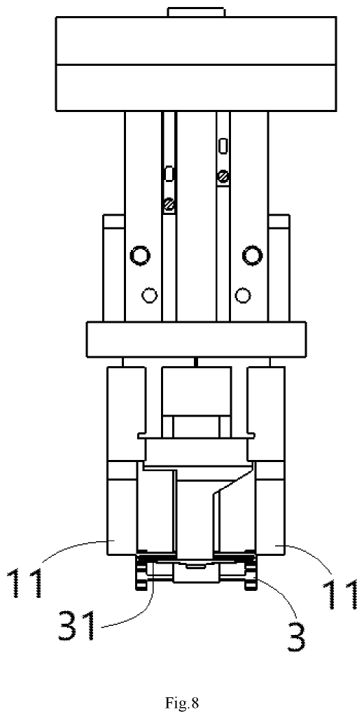

FIG. 6 shows a plan view of the pickup device 1 according to an exemplary embodiment of the present invention when viewed from the left side. FIG. 7 shows a cross-sectional view of the pickup device 1 according to an exemplary embodiment of the present invention. FIG. 8 shows a plan view of the pickup device 1 according to an exemplary embodiment of the present invention when viewed from the front side.

As shown in FIGS. 1-2 and 5-8, in the illustrated embodiment, the pickup device 1 further includes an installation block 14 and an elastic member 17. The installation block 14 is formed with an installation slot 141. The elastic member 17 is arranged in the installation slot 141. The upper part 122 of the holding claw 12 is slidably installed in the installation slot 141, and the clastic member 17 is compressed between the holding claw 12 and the installation block 14, allowing the holding claw 12 to float in a vertical direction relative to the installation block 14. In this way, it can ensure reliable contact between the holding claw 12 and the elastic clip 3, and can also slow down the impact of the holding claw 12 on the elastic clip 3.

As shown in FIGS. 1-2 and 5-8, in the illustrated embodiment, the installation block 14 has a top cover 142 that covers the top opening of the installation slot 141, and the elastic member 17 is compressed between the holding claw 12 and the top cover 142.

As shown in FIG. 7, the clastic member 17 is a spiral spring, with positioning blind holes formed on the holding claws 12 and the top cover 142, respectively. The two ends of the spiral spring are positioned in the positioning blind holes on the holding claws 12 and the top cover 142, respectively.

As shown in FIG. 2, in the illustrated embodiment, the elastic clip 3 includes a pair of clastic arms 33, a first crossbeam 31, and a second crossbeam 32. The first crossbeam 31 is connected between one ends of the pair of elastic arms 33. The second crossbeam 32 is connected between the other ends of the pair of elastic arms 33. In the illustrated embodiment, the first crossbeam 31 and the second crossbeam 32 of the elastic clip 3 are respectively formed with a first elastic clip 31a and a second elastic clip 32a for locking to a shielding shell 5 of a connector. The pair of clamping claws 11 are used to clamp on the left and right ends of the first crossbeam 31, and the holding claw 12 is used to press on the second crossbeam 32.

As shown in FIGS. 5-7, in the illustrated embodiment, the holding claw 12 has a pressing surface 12a for contact with the second crossbeam 32, which is inclined at a predetermined angle relative to the vertical direction. In an exemplary embodiment of the present invention, the inclination angle of the aforementioned pressing surface 12a depends on an inclination angle of the second elastic buckle 32a on the second crossbeam 32 relative to the vertical direction.

The pickup device 1 further includes a mounting member 16, on which a sliding groove 161 extending in the first horizontal direction is formed, as shown in FIG. 5. The upper parts 112 of the pair of clamping claws 11 are slidably installed in the sliding groove 161, allowing the pair of clamping claws 11 to move along the sliding groove 161.

As shown in FIGS. 5 and 6, in the illustrated embodiment, the pickup device 1 further includes a driver 13, which is connected to the pair of clamping claws 11 for driving the pair of clamping claws 11 to move along the sliding groove 161 to clamp or release the elastic clip 3. In an exemplary embodiment of the invention, the aforementioned driver 13 can be an electric cylinder, a cylinder or an electric servomechanism.

As shown in FIG. 5, in the illustrated embodiment, the width of the clamping claw 11 and the holding claw 12 in the first horizontal direction is less than half of the length of the first crossbeam 31 and the second crossbeam 32. The thickness of the lower parts 111 and 121 of the clamping claw 11 and the holding claw 12 in a second horizontal direction perpendicular to the first horizontal direction is less than half of the thickness of the upper parts 112 and 122 of the clamping claw 11 and the holding claw 12. In this way, the width and thickness dimensions of the lower parts 111 and 121 of the clamping claw 11 and the holding claw 12 can be reduced to prevent interference with other components during the clamping and installation of the elastic clip 3.

As shown in FIGS. 5 and 6, in the illustrated embodiment, the pickup device 1 further includes a connecting plate 15 for connecting to a robot 4. The installation block 14, installation component 16, and connecting plate 15 are fixed to the housing of the driver 13.

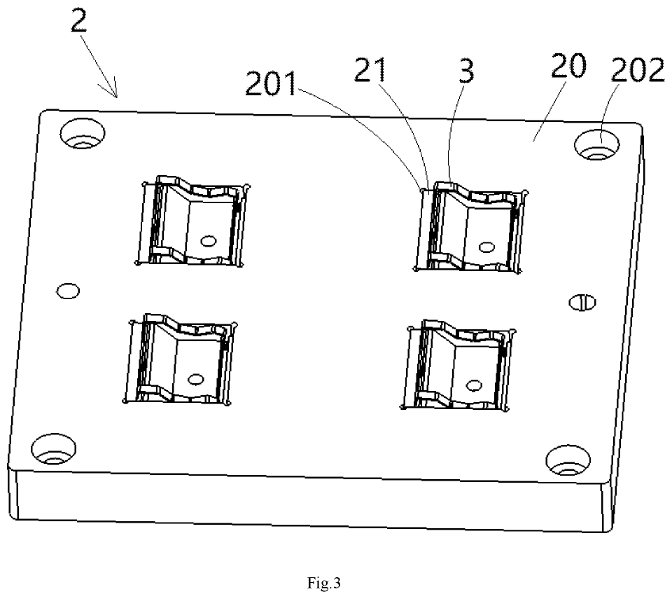

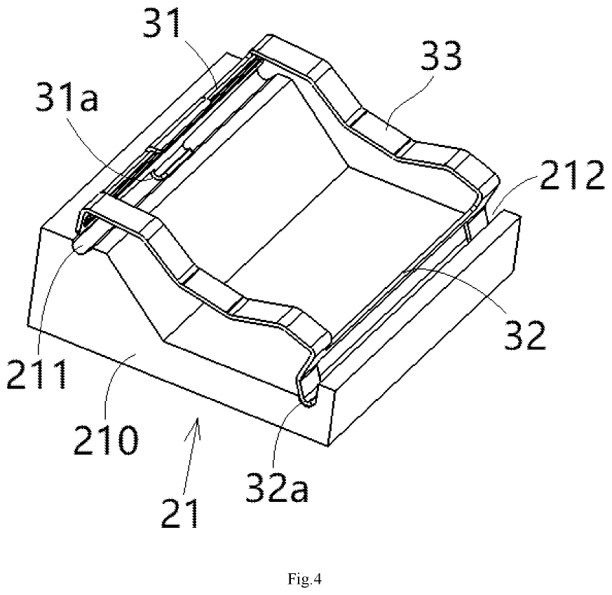

FIG. 3 shows an illustrative perspective view of loading tray 2 according to an exemplary embodiment of the present invention. FIG. 4 shows an illustrative perspective view of carrier 21 for loading tray 2 according to an exemplary embodiment of the present invention.

As shown in FIG. 3, in the illustrated embodiment, the loading tray 2 includes a tray body 20 and multiple carriers 21. Multiple installation slots 201 are formed on the tray body 20. Multiple carriers 21 are respectively embedded in multiple installation slots 201. A first positioning groove 211 and a second positioning groove 212 are formed on the carrier 21, as shown in FIG. 4, for positioning the first elastic buckle 31a and the second elastic buckle 32a respectively. In the embodiment shown in FIG. 3, a connecting hole 202 is also formed on the tray body 20, which can be connected to the installation platform 8 through bolts passing through the connecting hole 202.

As shown in FIG. 1, in the illustrated embodiment, the elastic clip installation system further includes a robot 4, and the pickup device 1 is installed on robot 4. Robot 4 is used to move and rotate the pickup device 1 to pick up the clastic clip 3 from the loading tray 2 and install the picked up elastic clip 3 onto the shielding shell 5.

As shown in FIG. 1, in the illustrated embodiments, the elastic clip installation system further includes a shielding shell fixture 7, which is used to clamp and fix the shielding shell 5 of the connector. The elastic clip 3 is installed on the shielding shell 5 that is clamped and fixed by the shielding shell fixture 7 to fix a heat sink 6 on the shielding shell 5.

As shown in FIG. 1, in the illustrated embodiments, the elastic clip installation system also includes a mounting platform 8. The robot 4, the loading tray 2, and the shielding shell fixture 7 are fixed on installation platform 8. Although not shown, the installation platform 8 can be a leg wheel hybrid installation platform equipped with rollers and support legs. When it is necessary to move, fold up the support legs and lower the rollers, and use the rollers to walk on the ground. When it is necessary to fix it in the predetermined working position, retract the roller and lower the support leg, and use the support leg to support the installation platform 8 in the predetermined working position.

It should be appreciated for those skilled in this art that the above embodiments are intended to be illustrative, and not restrictive. For example, many modifications may be made to the above embodiments by those skilled in this art, and various features described in different embodiments may be freely combined with each other without conflicting in configuration or principle.

Although several exemplary embodiments have been shown and described, it would be appreciated by those skilled in the art that various changes or modifications may be made in these embodiments without departing from the principles and spirit of the disclosure, the scope of which is defined in the claims and their equivalents.

As used herein, an element recited in the singular and preceded with the word “a” or “an” should be understood as not excluding plural of said elements or steps, unless such exclusion is explicitly stated. Furthermore, references to “one embodiment” of the present invention are not intended to be interpreted as excluding the existence of additional embodiments that also incorporate the recited features. Moreover, unless explicitly stated to the contrary, embodiments “comprising” or “having” an element or a plurality of elements having a particular property may include additional such elements not having that property.

What is claimed is:

1. An elastic clip installation system, comprising:
a loading tray on which an elastic clip to be installed is loaded; and
a pickup device picking up the elastic clip from the loading tray, the pickup device includes a pair of clamping claws and a holding claw, the clamping claws gripping the elastic clip from a left side and a right side of the elastic clip, the holding claw holding the elastic clip at a predetermined position on the loading tray to prevent movement of the elastic clip when the elastic clip is gripped by the clamping claws.

2. The elastic clip installation system according to claim 1, wherein the pickup device includes an installation block formed with an installation slot and an elastic member arranged in the installation slot.

3. The elastic clip installation system according to claim 2, wherein an upper part of the holding claw is slidably installed in the installation slot, the elastic member is compressed between the holding claw and the installation block, so that the holding claw is floatable relative to the installation block in a vertical direction.

4. The elastic clip installation system according to claim 3, wherein the installation block has a top cover that covers a top opening of the installation slot, the elastic member is compressed between the holding claw and the top cover.

5. The elastic clip installation system according to claim 4, wherein the elastic member is a spiral spring, a positioning blind hole is formed on each of the holding claw and the top cover, and a pair of ends of the spiral spring are respectively positioned in the positioning blind holes of the holding claw and the top cover.

6. The elastic clip installation system according to claim 2, wherein the elastic clip has a pair of elastic arms, a first crossbeam connected between a pair of first ends of the pair of elastic arms, and a second crossbeam connected between a pair of second ends of the pair of elastic arms.

7. The elastic clip installation system according to claim 6, wherein the pair of clamping claws clamp on a left end and a right end of the first crossbeam, the holding claw presses on the second crossbeam.

8. The elastic clip installation system according to claim 7, wherein the holding claw has a pressing surface contacting the second crossbeam, the pressing surface is inclined at a predetermined angle relative to a vertical direction.

9. The elastic clip installation system according to claim 7, wherein the pickup device includes a mounting piece on which a sliding groove extending in a first horizontal direction is formed.

10. The elastic clip installation system according to claim 9, wherein an upper part of each of the pair of clamping claws is slidably installed in the sliding groove and the pair of clamping claws move along the sliding groove.

11. The elastic clip installation system according to claim 10, wherein the pickup device includes a driver connected to the pair of clamping claws and driving the pair of clamping claws to move along the sliding groove to clamp or release the elastic clip.

12. The elastic clip installation system according to claim 10, wherein a width of the clamping claws and the holding claw in the first horizontal direction is less than half of a length of the first crossbeam and the second crossbeam.

13. The elastic clip installation system according to claim 10, wherein a thickness of a lower part of the clamping claws and the holding claw in a second horizontal direction perpendicular to the first horizontal direction is less than half of a thickness of the upper parts of the clamping claws and the holding claw.

14. The elastic clip installation system according to claim 11, wherein the pickup device includes a connecting plate connecting to a robot, the installation block, an installation piece, and the connecting plate are fixed to a housing of the driver.

15. The elastic clip installation system according to claim 6, wherein a first elastic buckle and a second elastic buckle for locking to a shielding shell of a connector are respectively formed on the first crossbeam and the second crossbeam of the elastic clip.

16. The elastic clip installation system according to claim 15, wherein the loading tray includes a tray body on which a plurality of installation slots are formed and a plurality of carriers embedded in the plurality of installation slots.

17. The elastic clip installation system according to claim 16, wherein a first positioning groove and a second positioning groove are formed on a carrier for positioning the first elastic buckle and the second elastic buckle respectively.

18. The elastic clip installation system according to claim 17, further comprising a robot on which the pickup device is installed, the robot is used to move and rotate the pickup device to pick up the elastic clip from the loading tray and install the elastic clip onto the shielding shell.

19. The elastic clip installation system according to claim 18, further comprising a shielding shell fixture clamping and fixing the shielding shell of the connector, the elastic clip is installed on the shielding shell clamped and fixed on the shielding shell fixture to fix a heat sink on the shielding shell.

20. The elastic clip installation system according to claim 19, further comprising an installation platform on which the robot, the loading tray, and the shielding shell fixture are fixed.
